(19) United States
(12) Patent Application Publication
(10) Pub. No.: US 2017/0271688 A1
(43) Pub. Date: Sep. 21, 2017

(54) Method for Preventing High Temperature Self Discharge in Primary Battery

(71) Applicant: The Charles Stark Draper Laboratory, Inc., Cambridge, MA (US)

(72) Inventors: Stanley Shanfield, Newton, MA (US); Adam Greenbaum, Boston, MA (US)

(21) Appl. No.: 15/462,224

(22) Filed: Mar. 17, 2017

Related U.S. Application Data
(60) Provisional application No. 62/309,664, filed on Mar. 17, 2016.

(51) Int. Cl. H01M 6/50; H02N 2/18; H01M 6/14; E21B 41/00; E21B 47/00; E21B 47/12; H02J 7/00; H01L 35/28

(52) U.S. Cl. CPC H01M 6/5072; H02J 7/0029; H02N 2/186; H01L 35/28; E21B 41/0085; E21B 47/00; E21B 47/12; H01M 6/14; H01M 2220/20

(57) ABSTRACT

A discharge prevention system for a primary battery comprises an energy harvesting module that produces energy from an environment and a control circuit for applying electrical current to the primary battery from the energy harvesting module to prevent or reduce self-discharge. This system will prevent or reduce rapid self-discharge at high temperatures in lithium-based primary batteries, for example. It can significantly extend the operating lifetime of such batteries operating at high temperature, particularly in applications where battery power is used intermittently. Specifically, a very low current is supplied to the primary battery at high temperature, significantly extending its storage lifetime. In some cases, depending on the current characteristics of the battery, the energy associated with the bias current can be in the same order of magnitude as the energy that would be lost by self-discharge, but in many cases it is much lower. This bias current “biases” the battery in such a way that self-discharge current of the primary battery is minimized.

### RELATED APPLICATIONS

This application claims the benefit under 35 USC 119(e) of U.S. Provisional Application No. 62/309,664, filed Mar. 17, 2016, which is incorporated herein by reference in its entirety.

### BACKGROUND OF THE INVENTION

A number of applications exist in which primary batteries are deployed to remote, high temperature environments. Satellites and spacecraft, such as planetary landers, must typically endure large temperature cycles. A terrestrial example is well drilling.

One specific example exists in petroleum and natural gas extraction. Sensor devices and data communication devices are typically placed down the well. These sensors can be mechanical or electronic devices for measuring various properties in the well such as pressure, fluid flow rate, temperature, vibration, and composition, for example.

The telemetry data produced by these sensors must also be transmitted to the surface. This data will typically be transmitted acoustically or electrically by downhole modems and repeaters back to a wellhead telemetry system. In a typical drilling environment, acoustic carrier waves from a telemetry sensor are modulated in order to carry information using the drill pipe and/or well casing as the transmission medium to the surface. Upon arrival at the surface, the waves are detected, decoded and information displayed in order that drillers and geologists can control the well. In production wells, downhole information can similarly be collected and analyzed.

All of these downhole devices can be permanent, or placed for months or longer, and they must be powered for that lifetime. The environment is often hot due to geothermal heating, however.

As a general rule, feasible rechargeable, or secondary, battery chemistries do not exist for high temperature environments. Thus, when the environmental temperatures exceed 100° C., or even 150° C. or 200° C., non-rechargeable, or primary, batteries are used. For example, Lithium Sulfuryl Chloride will work to about 150° C., whereas Lithium Thionyl Chloride is often employed when environmental temperatures approach 200° C.

### SUMMARY OF THE INVENTION

Lifetime is a critical metric for these downhole or extraterrestrial batteries. Recharging may not be an option due to the battery chemistry required to endure the high temperatures. However, even in the situation where a rechargeable chemistry were available, available power sources for recharging the batteries or even trickle charging the batteries may not be available due to cloud cover as in the case of Venus or because of the difficulty supplying electricity to a device located deep down a well.

In many primary Li-based batteries, self-discharge will have a significant impact on battery lifetime at elevated temperatures. For example, a Li Sulfuryl Chloride primary battery stored at 25° C. will suffer a capacity loss of approximately 3.5% per year. In contrast, the rate of self-discharge will be an order of magnitude higher as the temperature approaches 100° C. For a given battery design, the self-discharge rate power loss per unit time) appears to increase exponentially with temperature in an Arthenius relationship.

The present invention can be used to prevent rapid self-discharge at high temperature in lithium-based primary batteries, for example. The invention can significantly extend the operating lifetime of such batteries, when operating at high temperature, particularly in applications where battery power is used intermittently.

According to the invention, a very low current is supplied to the primary battery at high temperature, significantly extending its storage and/or operating lifetime. In some cases, the energy associated with the bias current can be in the same order of magnitude as the energy that would be lost by self-discharge (This depends on the detailed current-voltage (I-V) characteristics of the battery at its open circuit voltage, and can be significantly less than the energy that would have been lost.) The bias charge does not “replace” the energy that would have been lost through self-discharge. Instead, the bias current “biases” the battery in such a way that self-discharge current of the primary battery is minimized. In short, the present system does not rely on charging a type of battery that cannot be recharged. Instead, the battery is electrically biased to reduce self-discharge.

In general, according to one aspect, the invention features a discharge prevention system for a primary battery. This system comprises an energy harvesting module that produces energy from an environment and a control circuit for applying an electrical bias current to the primary battery from the energy harvesting module to prevent or reduce self-discharge.

For typical applications, the primary battery is a Lithium Sulfuryl Chloride battery or a Lithium Thionyl Chloride battery. Both types of batteries can operate at high temperatures.

In one application, the discharge prevention system is implemented in a downhole device in a well. Such a device can have a wake-up module for periodically activating a controller powered by the primary battery.

In another example, the discharge prevention system is utilized in a spacecraft.

To prevent or reduce discharge, the control circuit only needs to apply less than I milliAmpere (mA) to the primary battery, and even less than 100 microAmperes (μA) is adequate in some cases. Stated more generally, the control circuit typically applies a bias current that is at least 500 times less than a rated maximum continuous current of the primary battery.

In general, according to another aspect, the invention features a method for preventing self-discharge of a primary battery. This method comprises producing electrical energy from an environment and applying electrical current to the primary battery to prevent or reduce self-discharge.

In general, according to still another aspect, the invention features a downhole device for a well. This device comprises a device controller, a primary battery for powering the controller, an energy harvesting module that produces energy from an environment, and a control circuit for applying electrical current to the primary battery from the energy harvesting module to prevent or reduce self-discharge.

The above and other features of the invention including various novel details of construction and combinations of parts, and other advantages, will now be more particularly described with reference to the accompanying drawings and pointed out in the claims. It will be understood that the particular method and device embodying the invention are shown by way of illustration and not as a limitation of the invention. The principles and features of this invention may be employed in various and numerous embodiments without departing from the scope of the invention.

### BRIEF DESCRIPTION OF THE DRAWINGS

In the accompanying drawings, reference characters refer to the same parts throughout the different views. The drawings are not necessarily to scale; emphasis has instead been placed upon illustrating the principles of the invention. Of the drawings:

FIG. 1 is a circuit diagram for modeling the primary battery;

FIG. 2 is a plot of a self-discharge compensation circuit as a function of temperature for an exemplary battery;

FIG. 3 is a schematic diagram showing a well drilling operation;

FIG. 4 is a block diagram of an exemplary downhole communications device; and

FIG. 5 is a block diagram of an exemplary downhole sensor device.

### DETAILED DESCRIPTION OF THE PREFERRED EMBODIMENTS

The invention now will be described more fully hereinafter with reference to the accompanying drawings, in which illustrative embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

As used herein, the term “and/or” includes any and all combinations of one or more of the associated listed items. Further, the singular forms and the articles “a”, “an” and “the” are intended to include the plural forms as well, unless expressly stated otherwise. It will be further understood that the terms: includes, comprises, including and/or comprising, when used in this specification, specify the presence of stated features, integers, steps, operations, elements, and/or components, but do not preclude the presence or addition of one or more other features, integers, steps, operations, elements, components, and/or groups thereof. Further, it will be understood that when an element, including component or subsystem, is referred to and/or shown as being connected or coupled to another element, it can be directly connected or coupled to the other element or intervening elements may be present.

It is not immediately obvious how a small compensation current delivered to a primary battery would result in a significant operating life extension. However, the voltage-current characteristic of these (and most) batteries is highly non-linear, i.e. in certain regions of the battery I-V characteristic, a very small change in battery current results in a very large change in battery voltage, while a small change in battery current will mean a very small change in voltage in other regions of the battery characteristic.

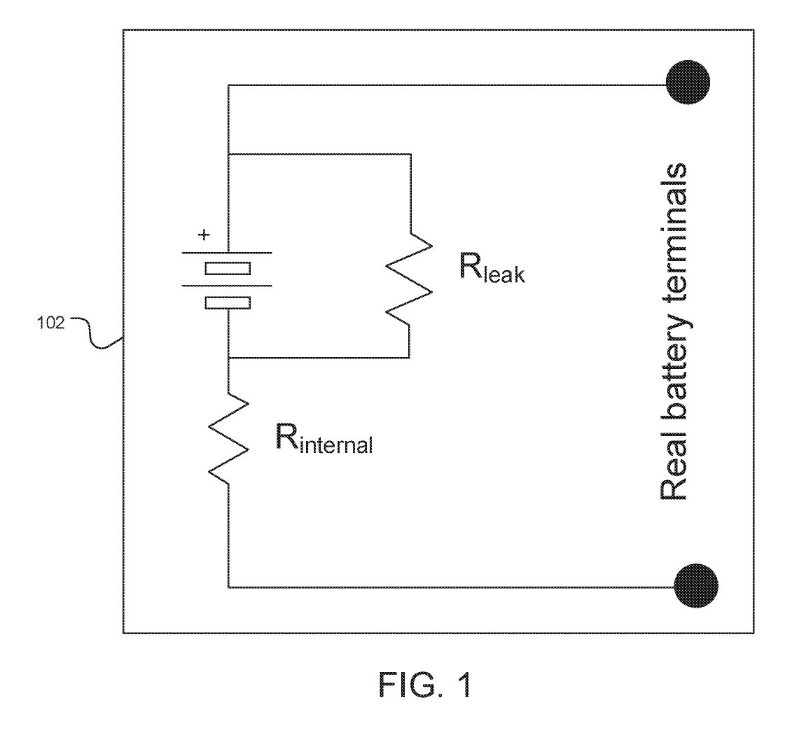

This non-linear behavior can be modeled with an equivalent circuit consisting of an ideal voltage source (zero internal impedance), a resistor Rₜₑₐₖ, in parallel with the ideal voltage source, representing a thermally activated current leakage path of self-discharge, and a series resistor Rᵢₙₜₑᵣₙₐₗ, representing the output impedance of the battery (see FIG. 1). From inspection of this equivalent circuit, it is apparent that a low current (applied with the same polarity as the ideal battery, but at the real battery terminals) can entirely shut off the internal leakage current coming from the ideal voltage source. For a AA Li Sulfuryl Chloride battery, typical values at 72° C. are Rₜₑₐₖ=50,000-60,000 Ohms (Ω), and Rᵢₙₜₑᵣₙₐₗ=1.6 Ω.

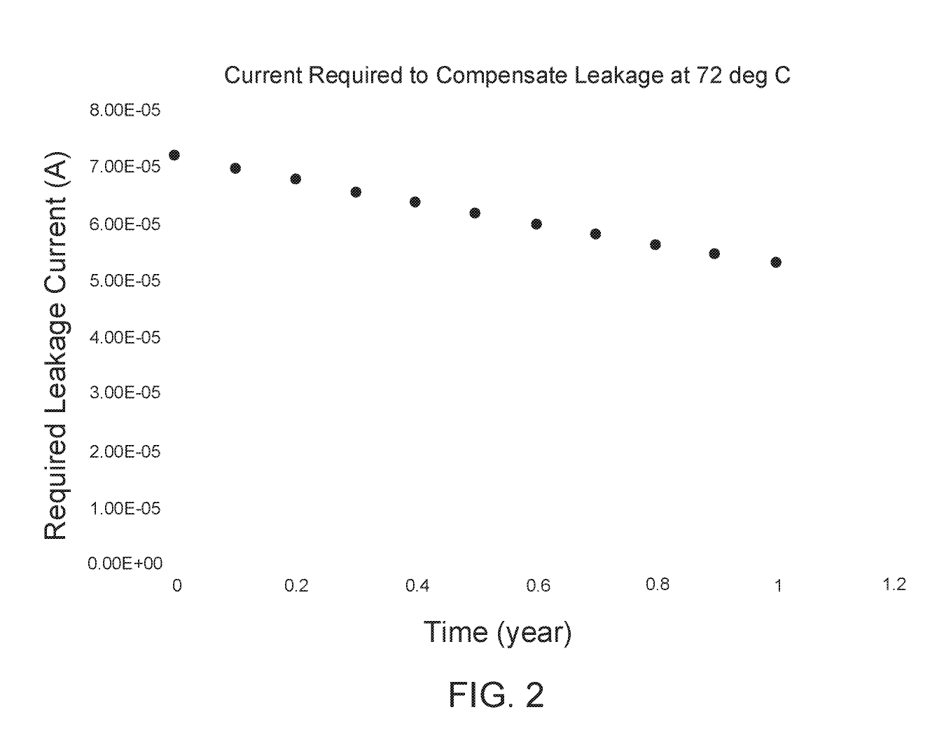

In FIG. 2, the calculated compensation current for this battery is plotted over one year of storage at 72° C., where the open circuit voltage of the battery is 3.35 V. The required bias current levels are relatively small, in the range of 60 microAmperes (μA)−70 μA or less, meaning that the supplied power per module is about 235 microwatts (μW) or less.

This bias current much lower than the rated maximum continuous current for the battery. In one example, for a AA battery, the rated maximum continuous current was 150 mA, yet the required bias current was only about 70 μA. Thus, in most cases, the bias current will be over 500 times less than the rated maximum continuous current, and is typically 1000 times or 2000 times less.

A number of advantages arise from this approach. It does not require any changes or adaptations to the battery design, but may allow for nearly indefinite storage life at high temperature for high temperature batteries. Thus, the batteries can be maintained for powering sensing and acoustic transmit/receive units placed within a downhole hydrocarbon recovery well at various depths. They can also maintain batteries for supplying power to sensing and acoustic transmit/receive units placed within environmental monitoring wells, looking for trace pollutants or maintaining readiness in batteries used intermittently in high temperature conditions found in aircraft or automobiles.

The approach is compatible with energy scavenging/harvesting systems (such as photovoltaic cells, thermoelectric elements, acoustic or vibration energy or inductive collection) which typically have very low power output which is nevertheless enough to reduce the self-discharge.

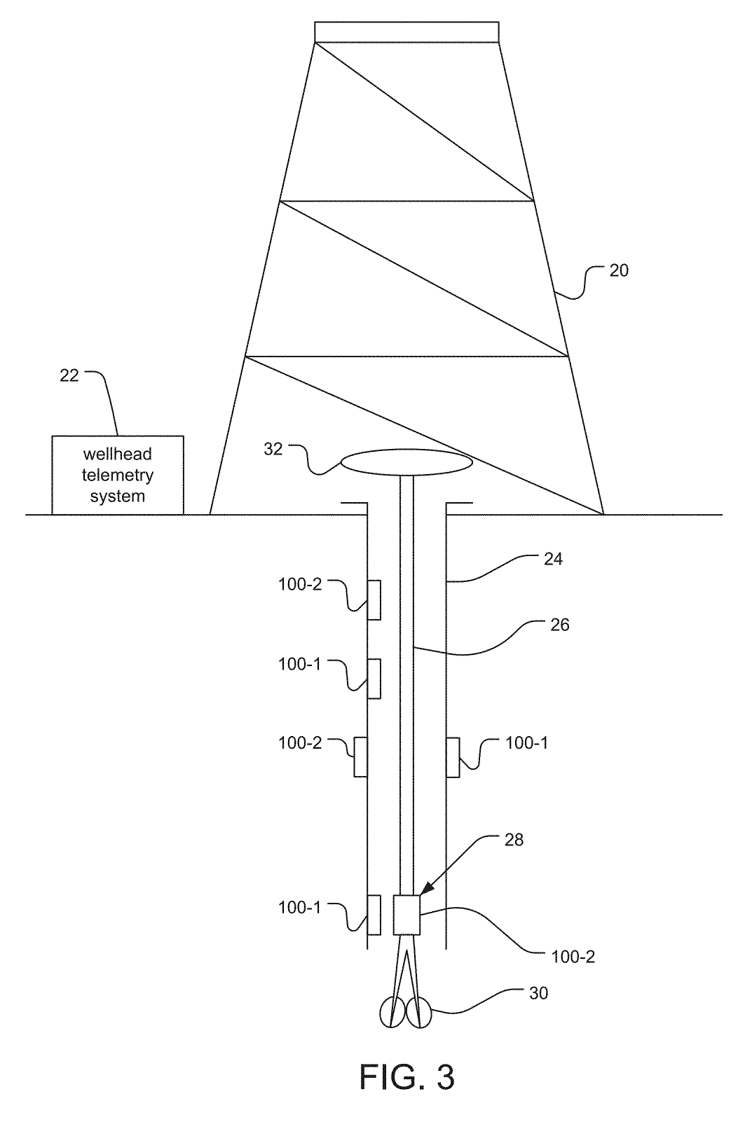

FIG. 3 shows an example of a well drilling rig. A derrick 20 is located above the well. It is used to lift drill pipe and well casing sections over the well. A turntable 32 is used to drive the drill pipe 26 that extends down the well. Typically, for at least a portion of the well, it is lined with the well casing 24.

Toward the end of the drill pipe 26, there is typically a drill collar 28 that the pipe to the drill bit 30, which cuts through the earth and rock.

Relevant to the invention is the use of downhole devices 100 that are typically located at different depths within the well and typically near the drill bit. In the illustrated example, sensor devices 100-1 include transducers that detect physical properties within the well. Communication devices 100-2 collect the data from the sensor devices 100-1 and encode the data so that it can be transmitted to the wellhead telemetry system 22 at the surface. Typically, these communication devices 100-2 might comprise modems for modulating the data and repeater devices that may line the well reaching to the surface to relay the data until it can be input into the telemetry system 22. Some of these devices 100 might be located in the collar and relatively accessible. Other devices 100, however, might be located along or even outside the casing 24.

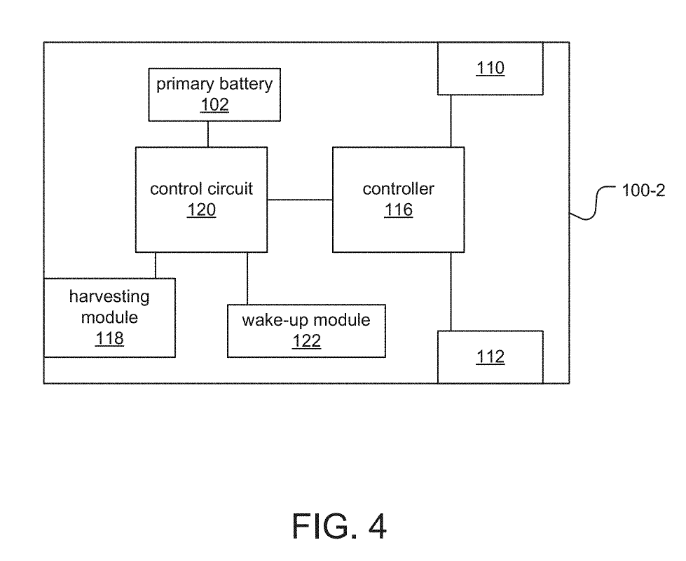

FIG. 4 shows an example of a downhole communication device 100-2. In the illustrated example, it comprises a data receiver 112 for receiving data, such as from another communication device or a sensor device 100-1. Often, this data is transmitted by modulating acoustic waves. However, in other examples, it can be transmitted electrically. This data is received and interpreted by the controller 116 and then transmitted from the communications device 100-2 via the data transmitter 110.

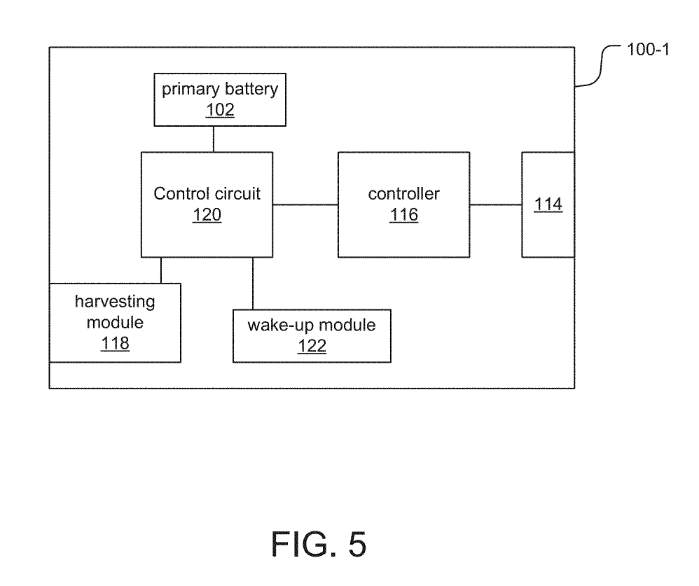

FIG. 5 shows the example of a sensor device 100-1. It also comprises a controller 116 that monitors a sensor transducer 114. In various examples, the sensor transducer can be, for example, a thermistor for detecting temperature. In other examples, transducer 114 is a pressure sensor or flow sensor for detecting a fluid such as gas or petroleum flowing through the casing. In other examples, it can be an acoustic sensor for detecting vibration associated with the drilling operation. Different acoustic sensors may be used, e.g. accelerometer, measurement microphone, contact microphone, and hydrophone.

According to the exemplary configuration, at least one, but more typically each acoustic sensor either has a built-in amplifier or is connected to an amplifier (not shown) directly. The drilling acoustic signals picked up by the acoustic transducer 114 are amplified first by the amplifier and are then transmitted to the controller 116.

Most relevant to the invention in both FIGS. 4 and 5 is the inclusion of the primary battery 102 for powering the downhole devices 100. Further, energy harvesting module 118 provides power to a control circuit 120 that applies electrical current from the energy harvesting module 118 to the primary battery 102 to prevent its self-discharge.

As described previously, often the battery 102 is a Lithium Sulfuryl Chloride or Lithium Thionyl Chloride battery.

A number of different examples exist for the energy harvesting module 118. For example, energy harvesting module 118 is powered from an electrical current supplied from the wellhead. In other examples, it includes a piezo electric transducer for converting the vibration associated with the drilling operation into a small current. In other examples, the energy harvesting module is powered by a turbine that is rotated by the movement of fluid within the casing or drill pipe 26. If a thermal gradient is available, then a thermoelectric power source or Stirling engine could be used as the energy harvesting module 118.

In any event, the energy harvesting module 118 provides a low current that is applied by the control circuit 122 to the primary battery 102. In general, this current is less than 1 milliAmpere. Typically, however, it is less than 100 μA.

In a typical implementation, the downhole device 100 is mostly dormant or inactive. A wake-up module 122, however, periodically switches the control circuit 120 from supplying the small bias current from the energy harvesting module 118 to supplying power to the controller 116. In one example, the duty cycle of the device is less than 5%, between active and dormant states.

While this invention has been particularly shown and described with references to preferred embodiments thereof, it will be understood by those skilled in the art that various changes in form and details may be made therein without departing from the scope of the invention encompassed by the appended claims.

What is claimed is:

1. A discharge prevention system for a primary battery, comprising:
an energy harvesting module that produces energy from an environment; and
a control circuit for applying electrical bias current to the primary battery from the energy harvesting module to prevent or reduce self-discharge.

2. A system as claimed in claim 1, wherein the primary battery is a Lithium Sulfuryl Chloride battery.

3. A system as claimed in claim 1, wherein the primary battery is a Lithium Thionyl Chloride battery.

4. A system as claimed in claim 1, wherein the discharge prevention system is implemented in a downhole device in a well.

5. A system as claimed in claim 1, wherein the downhole device comprises a wake-up module for periodically activating a controller powered by the primary battery.

6. A system as claimed in claim 1, wherein the discharge prevention system is utilized in a spacecraft.

7. A system as claimed in claim 1, wherein the control circuit applies less than 1 milliAmpere bias current to the primary battery.

8. A system as claimed in claim 1, wherein the control circuit applies a bias current that is 500 times less than a rated maximum continuous current of the primary battery.

9. A system as claimed in claim 1, wherein the control circuit applies a constant current to the primary battery from the energy harvesting module.

10. A method for preventing self-discharge of a primary battery, comprising:
producing electrical energy from an environment; and
applying an electrical bias current to the primary battery to prevent or reduce self-discharge.

11. A method as claimed in claim 10, wherein the primary battery is a Lithium Sulfuryl Chloride battery.

12. A method as claimed in claim 10, wherein the primary battery is a Lithium Thionyl Chloride battery.

13. A method as claimed in claim 10, further wherein the discharge prevention system is utilized in a downhole device in a well.

14. A method as claimed in claim 10, further comprising applying less than 1 milliAmpere to the primary battery.

15. A method as claimed in claim 10, further comprising applying a bias current that is 500 times less than a rated maximum continuous current of the primary battery.

16. A method as claimed in claim 10, further comprising applying a constant current to the primary battery from the energy harvesting module when the device is dormant.

17. A downhole device for a well, comprising:
a device controller;
a primary battery for powering the controller;
an energy harvesting module that produces energy from an environment; and
a control circuit for applying an electrical bias current to the primary battery from the energy harvesting module to prevent or reduce self-discharge.

18. A device as claimed in claim 17, wherein the primary battery is a Lithium Sulfuryl Chloride battery.

19. A device as claimed in claim 17, wherein the primary battery is a Lithium Thionyl Chloride battery.

20. A device as claimed in claim 17, further comprising a wake-up module for periodically activating a device controller powered by the primary battery.
